(19) United States
(12) Patent Application Publication
(10) Pub. No.: US 2022/0136102 A1
(43) Pub. Date: May 5, 2022

(54) CHEMICAL VAPOR DEPOSITION APPARATUS

(71) Applicant: SHANGHAI ALPHATOMIC MANAGEMENT CONSULTING LIMITED PARTNERSHIP, Shanghai (CN)

(72) Inventor: Xin Ding, Shanghai (CN)

(21) Appl. No.: 17/431,569

(22) PCT Filed: Sep. 11, 2019
(86) PCT No.: PCT/CN2019/105422

§ 371 Date: Aug. 17, 2021

(30) Foreign Application Priority Data
Sep. 11, 2018 (CN) 201811055932.0

(51) Int. Cl. C23C 16/458; C23C 16/52; C23C 16/46

(52) U.S. Cl. CPC C23C 16/4584; C23C 16/46; C23C 16/52

(57) ABSTRACT

The present invention provides a chemical vapor deposition equipment. The equipment includes a reaction chamber, the reaction chamber includes a plurality of bases for bearing substrates, the plurality of bases are disc-shaped, process gas enters the reaction chamber through a pipeline, each base of the plurality of bases is arranged in parallel to each other, and circle centers of the bases are on a same straight line; upper surfaces of the bases bearing the substrates are parallel to each other or on a same plane; rotation axes of the bases are on a same plane, and the bases rotate independently relative to each other; and the process gas flows along the upper surfaces of the bases and in a direction perpendicular to a connecting line of the circle centers of the bases.

### TECHNICAL FIELD

The present invention relates to the field of chemical vapor deposition, and specifically relates to chemical vapor deposition equipment.

### BACKGROUND

Chemical Vapor Deposition (CVD) is a thin film growth technology widely used in fields of semiconductor and flat panel display. A growth rate of the vapor deposition technology is relatively low. At the same time, due to a high reaction temperature, a large amount of non-metallic materials such as graphite, quartz, ceramics is usually used to make components of a metal reaction chamber. Limited by a processing technology of such materials, costs of such components in the reaction chamber are very high, and consequently costs of film formation are relatively high.

In the prior art, one way to solve the problem of production costs for high-temperature CVD is to use a multi-piece plate structure. On a large disc base, a large quantity of substrates is placed in a centrosymmetric manner. In order to improve uniformity of film formation, a common practice is that the disc base rotates around the center to make film formation on the same radius more consistent. The advantage is that the cost of film formation is lower than that of a single-piece design with one substrate, but the uniformity of film formation is also lower than that of the single-piece design with one substrate.

The uniformity of film formation refers to consistency of specified parameters such as film thickness and resistance at different physical locations on the substrate. Usually, several points on the substrate are taken to measure and calculate the deviation.

Other prior art has made improvements to the above multi-piece structure, and the method is placing a planetary rotary disc that can rotate independently under each substrate on the large disc base. When an air flotation technology is used to make the big disc base revolve, each planetary rotary disc can be suspended on the large disc base for independent planetary rotation. This technology is also called a planetary design. This method can improve uniformity of film formation, but also has obvious shortcomings. For example, an air flotation pipeline of the disc base is made of graphite material with holes, and therefore production costs are relatively high. It is difficult to independently control the rotation speed, and therefore repeatability of film formation is reduced. In addition, when the size of the substrate increases, the self-weight of the substrate and a small disc base increases, and it becomes more difficult to implement air suspension rotation of a disc. Consequently, it is difficult to use this method for large-sized substrates.

### SUMMARY

To solve the problem, the present invention provides a new type of chemical vapor deposition reaction equipment in which a large quantity of substrates is placed, and having high productivity and high uniformity of film formation.

According to a first aspect, chemical vapor deposition equipment is disclosed, including a reaction chamber, where the reaction chamber includes a plurality of bases for bearing substrates, the plurality of bases are disc-shaped, and process gas enters the reaction chamber through a pipeline, the bases in the plurality of bases are arranged in parallel, and circle centers of the bases are on the same straight line;

the upper surfaces of the base bearing substrates are parallel to each other or on the same plane;

rotation axes of the bases are on the same plane, and the bases rotate independently relative to each other; and

the process gas flows along the upper surface of each base, and in a direction perpendicular to a line connecting the circle centers of the bases.

Further, an inner box is further included between the reaction chamber and the base, and a shape of the inner box includes a cuboid; and the reactant gas flows along the upper surface of the base in a direction relatively parallel to short sides of a rectangle obtained by cutting by using the upper surface and a cross section of the inner box.

Further, the adjacent bases rotate in directions opposite to each other.

Further, the chemical vapor deposition equipment further includes a mass flow meter, a common mass flow meter is used for the plurality of bases, and the mass flow meter distributes the process gas to the bases; and a regulating valve is disposed on the pipeline through which the process gas flows from the mass flow meter to the base.

Further, the chemical vapor deposition equipment further includes a transfer chamber and a mechanical transfer arm, the transfer chamber is polygonal, at least one side of the transfer chamber is provided with a transfer station of the substrate, and the reaction chamber is provided on each of the remaining sides; and the mechanical transfer arm is located in the transfer chamber, and transfers the substrate to the plurality of bases of the reaction chamber.

Further, the mechanical transfer arm is further configured to move along a direction parallel to the connecting line of the circle centers of the bases in the reaction chamber.

Further, a base extension part is filled between the bases, a material of the base extension part is the same as that of the base, and an upper surface of the base extension part and the upper surface of the base are on the same plane.

Further, the upper surface of the base extension part includes one or more of a shield, a protrusion, a depression, a guide fin, and a positioning point.

Further, there is an elevation difference between the upper surface of the base extension part and the upper surface of the base, and the elevation difference can be adjusted manually or automatically by using a mechanical structure.

Further, the inner box is made of a non-metallic high-temperature-resistant and corrosion-resistant material.

Further, a heating body is provided between the reaction chamber and the inner box, the heating body includes an infrared lamp source, a resistance heater, and the resistance heater includes a metal or graphite resistance heater.

Further, a driving method of the metal resistance heater or the graphite resistance heater further includes exciting metal or graphite by using an induction coil radio frequency, to cause the metal resistance heater or the graphite resistance heater to generate heat.

Further, the resistance heater is spiral shaped.

Further, the resistance heater further includes at least one of the following heaters:

a ring heater centered on the circle center of the base;
an arc heater centered on the circle center of the base;
point heaters, where the point heaters are distributed on a plurality of rings centered on the circle center of the base, or distributed in a honeycomb pattern centered on the circle center of the base; and

line heaters, where the line heaters are distributed in a direction perpendicular or parallel to the connecting line of the circle centers of the bases, or the line heaters are distributed along a radial direction of the base.

Further, a heat-insulation material is provided between the heating body and the reaction chamber.

Compared with the prior art, main differences and effects of the embodiments of the present invention are as follows:

In the embodiments of the present application, two or more disc bases are arranged at low cost in the chemical vapor deposition equipment, and these disc bases can share gas flow controllers or fewer heaters by using pipelines. In this way, film-formation can be performed on more disc bases, and costs of a reaction chamber and other equipment supporting the reaction chamber are greatly reduced, so that the manufacturing cost of the entire set of equipment is reduced. At the same time, consumption of reactant gas and energy for heating can also be reduced, so that the amount of consumables for film formation can also be reduced. In addition, the same film uniformity as the single-piece disc base is achieved while the above low-cost solution is implemented.

### BRIEF DESCRIPTION OF DRAWINGS

FIG. 1 is a top view of chemical vapor deposition equipment according to an embodiment of the present invention.

FIG. 2 is a schematic connection diagram of a mass flow meter of chemical vapor deposition equipment according to an embodiment of the present invention.

FIG. 3 is a schematic diagram of a vertical cross-section of a shape and an arrangement of a heating body of chemical vapor deposition equipment according to an embodiment of the present invention.

FIG. 4 is a top view of a shape and an arrangement of a heating body of chemical vapor deposition equipment according to an embodiment of the present intention.

FIG. 5 is a top view of a shape and an arrangement of another heating body of chemical vapor deposition equipment according to an embodiment of the present invention.

FIG. 6 is a schematic diagram of a vertical cross-section of a shape and an arrangement of another heating body of chemical vapor deposition equipment according to an embodiment of the present invention.

FIG. 7 is a top view of a shape and an arrangement of another heating body of chemical vapor deposition equipment according to an embodiment of the present invention.

FIG. 8 is a schematic configuration diagram of an arc-shaped heating body of chemical vapor deposition equipment according to an embodiment of the present invention.

FIG. 9 is a schematic diagram of a complete disc spiral heater of chemical vapor deposition equipment according to an embodiment of the present invention.

FIG. 10 is a schematic diagram of zone division of a complete disc spiral heater of chemical vapor deposition equipment according to an embodiment of the present invention.

FIG. 11 is a schematic diagram of disposing a heat-insulation container between a heat source and a reaction chamber of chemical vapor deposition equipment according to an embodiment of the present invention.

FIG. 12 is a schematic diagram of disposing a heat-insulation layer between a heat source and a reaction chamber of chemical vapor deposition equipment according to an embodiment of the present invention.

FIG. 13 is a schematic diagram of a pipeline configuration of chemical vapor deposition equipment according to an embodiment of the present invention.

FIG. 14 is a schematic diagram of another pipeline configuration of chemical vapor deposition equipment according to an embodiment of the present invention.

FIG. 15 is a simplified three-dimensional schematic diagram of chemical vapor deposition equipment according to an embodiment of the present invention.

FIG. 16 is a schematic diagram of a chemical vapor deposition system according to an embodiment of the present invention.

### DETAILED DESCRIPTION OF EMBODIMENTS

In order to make objectives and technical solutions of embodiments of the present invention clearer, the technical solutions of the embodiments of the present invention are described clearly and completely with reference to the accompanying drawings of the embodiments of the present invention. Obviously, the described embodiments are part of the embodiments of the present invention, but not all of the embodiments. Based on the described embodiments of the present invention, all other embodiments obtained by a person of ordinary skill in the art without creative efforts shall fall within the protection scope of the present invention.

In the present invention, a reaction chamber includes a metal vacuum, low pressure, normal pressure or high pressure container, and also includes the above container and spare parts in the container, such as a nozzle, a graphite base, a quartz or ceramic part, and a heater, suitable for performing thermochemical vapor deposition. In a broader sense, the reaction chamber may also include pipelines for supplying reactant gas, valves, mass flow meters, circuits, etc., and the present invention is not limited herein.

In the present invention, the base is usually made of high-temperature-resistant materials such as metal, ceramics, quartz, high-purity graphite, or carbide-coated graphite. The base may include a rotatable disc that carries a silicon wafer or a substrate of other materials, or may include a rotatable disc that carries a silicon wafer or other substrate and other non-rotatable parts outside the disc.

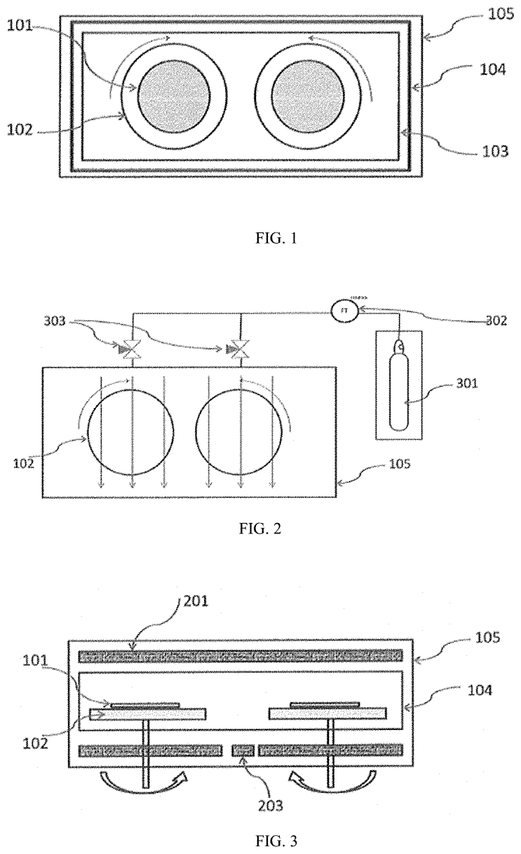

FIG. 1 is a top view of chemical vapor deposition equipment according to an embodiment of the present invention. In FIG. 1, 101 is a substrate to be processed, 102 is a disc base, 103 is a base extension part, 104 is an inner box, and 105 is a reaction chamber.

According to an embodiment of the present invention, a plurality of disc bases 102 may be arranged in parallel. Diameters of the substrates 101 contained in the disc bases 102 are 100 mm, 150 mm, 200 mm, 300 mm, 450 mm, etc. In some cases, the substrate 101 may also be a square sheet (rectangular or square). A material of the substrate 101 may be metal, glass, quartz, silicon, germanium, sapphire, aluminum nitride, gallium nitride, gallium arsenide, silicon carbide, graphene, and the like.

As an example, a diameter of the disc base 102 is usually 1.1 to 1.5 times of the diameter of the substrate 101. Generally, a smaller substrate 101 can also be placed on a larger disc base 102. For example, a substrate 101 of 150 mm can be placed on a base that originally matches a substrate 101 of 200 mm, and a substrate 101 of 200 mm can also be placed on a base of 300 mm provided that a suitable recess is dig out on the original larger base.

According to the embodiment of the present invention, circle centers of the disc bases 102 are on a same straight line, and upper surfaces of the disc bases 102 (or the substrates 101 placed on the surfaces of the bases) are on a same plane; or upper surfaces of these disc bases 102 (or the substrates 101) are parallel to each other, and rotation axes of the disc bases 102 are on a same plane. A single disc base 102 rotates around its center. Reactant gas or process gas flows along the surface of the disc base 102 (or the substrate 101) in a vertical direction of a connecting line of the circle centers of the disc bases 102.

As another example, when there are more than three disc bases 102, a circle center of one of the more than three disc bases 102 is allowed to slightly deviate from the connecting line of the circle centers of the other disc bases 102. A little deviation does not have a greater impact on process performance, that is, uniformity of film formation. The deposited films include silicon, germanium, sapphire, silicon oxide, silicon nitride, aluminum nitride, gallium nitride, gallium arsenide, silicon carbide, graphene, etc.

As shown in FIG. 1, adjacent disc bases 102 can rotate in a same direction or in opposite directions. A rotation speed is in a range of 0-60 RPM. Preferably, the adjacent bases 102 rotate in the opposite directions. When the adjacent disc bases 102 rotate in the opposite directions, for example, a disc base 102 that rotates clockwise is adjacent to a base that rotates counterclockwise; on the contrary, a base 102 that rotates counterclockwise is adjacent to a base that rotates clockwise. In this case, directions of linear velocities of adjacent edge portions of the adjacent disc bases 102 point to a same direction in a parallel manner, so that disturbance of the reactant gas can be minimized, and a good laminar flow can be maintained.

In addition, gaps that are not covered by the disc bases 102 are provided on extension planes of the upper surfaces of the disc bases 102. In order to maintain a uniform temperature distribution, a flat part made of the same or similar material as the disc base 102 can be used to cover these gaps. The part covering these gaps are referred to as a base extension part 103. When process processing is performed in the reaction chamber 105, an upper surface of the part(s) and the upper surface of a small disc base 102 (a substrate 101) are on a same plane, or there is a slight difference of elevation at most. A little difference of elevation does not have a major impact on the process performance, that is, uniformity of film formation, and a gas flow rate of the reaction chamber 105 can be controlled by adjusting the difference of elevation, adjusting the difference of elevation is a possible process adjustment method, and the difference of elevation can be manually or automatically adjusted by using a mechanical structure. It is not shown in FIG. 1, but a shield, a protrusion, a depression, a guide fin, a positioning point (block), etc., designed based on process requirements, can be provided on the surface of the base extension part 103, and can be used to adjust the distribution of gas and temperature in the reaction chamber 105, to help improve the uniformity of film formation.

Next, FIG. 2 is a schematic connection diagram of a mass flow meter. In FIG. 2, 301 is a gas source (gas cylinder, gas tank, etc.) that provides process gas, 302 is a mass flow meter that controls a gas flow, and 303 is a throttle valve. As shown in FIG. 2, a common mass flow meter 302 can be used for a plurality of disc bases 102 or several disc bases 102 in the plurality of disc bases 102, and gas flowing out of the same mass flow meter 302 is evenly distributed to the disc bases 102 by using a gas piping and flows over the upper surfaces of the disc bases 102 for processing to ensure the uniformity of film formation. Since gas piping flowing into the respective disc base 102 after the mass flow meter 302 has a slightly different effect on the gas flow rate, etc., a regulating valve, for example, the throttle valve 303, can be disposed on the respective pipeline before flowing into the respective disc base 102 after flowing out of the mass flow meter 302, and the throttle valve 303 can be a manual needle valve or an actuated throttle valve. The throttle valve 303 is used to compensate for deviation in the pipelines after the flow meter to compensate for uniformity of final film formation. Optionally, more throttle valves can be additionally designed on a cross section of each disc base 102 to divide process gas flow flowing through a single disc base 102 (a substrate 101) into more zones for independent control.

According to an embodiment of the present invention, disc base 102 and the like may be arranged in a closed container made of metal, such as stainless steel or aluminum. In some scenarios, the closed container made of metal is also called a reaction chamber 105. A short side of an inner wall of the reaction chamber 105 is 125 mm-810 mm, a long side is about an integer multiple of the length of the short side, and the multiple is the number of disc bases 102. The reaction chamber 105 is isolated from outside by using a flange and a valve at the flange. Cooling water is connected to the reaction chamber 105 through a pipeline, process gas through a nozzle, and a power supply through an electrodes and a drive shaft of the disc base 102, to provide a process environment or conditions required for chemical vapor deposition. A cuboid or a shape similar to a cuboid is designed in the reaction chamber 105. For example, a basic shape is an inner box 104 with openings, holes, or steps on a cuboid, and an arched upper surface to resist air pressure or connect other shaped parts. The inner box 104 can accommodate the disc base 102 and the base extension part 103. Similarly, the inner box 104 is isolated from outside by using a flange and a valve at the flange, cooling water is connected to the inner box 104 through a pipeline, process gas through a nozzle, and a power source through an electrode and a drive shaft of the disc base 102.

In the inner box 104, reactant gas flows along a surface of a disc base 102 (a substrate 101) in a direction parallel to a short side of a rectangle obtained by cutting by using this plane and a cross section of the inner box, or flows along the disc base 102 (the substrate 101) in a direction perpendicular to connecting line of circle centers of the disc bases 102.

Because the inner box 104 is exposed to a high temperature and possibly corrosive process gas environment, the inner box 104 is usually made of non-metallic high-temperature-resistant and corrosion-resistant materials such as quartz, glass, ceramics, graphite, and coated graphite.

A heating body (heat source) is provided between the reaction chamber 105 and the inner box 104 to heat the substrate 101 to a required reaction/process temperature, and a process temperature range of the substrate 101 is 100-2800° C. The heating body can be an infrared lamp source, metal or graphite or coated graphite resistance heater. Graphite or coated graphite or metal resistance heater can be directly connected to a power supply, or can excite graphite or metal by using an induction coil radio frequency or the like to generate heat. The heating body can heat the substrate 101 directly or indirectly. For example, infrared radiation can directly penetrate the inner box 104 made of quartz to directly heat the disc base 102 and the substrate 101. When material of the inner box 104 shows a characteristic of strongly absorbing infrared radiation, ceramic or coated graphite inner box 104 is heated in an indirect manner, and after the inner box 104 absorbs heat radiated by the resistance heater, heat is radiated to the disc base 102 again to heat the disc base 102 and the substrate 101.

Referring to FIG. 3 to FIG. 10, a shape and an arrangement of a heating body (a heat source) in an embodiment of the present invention is described.

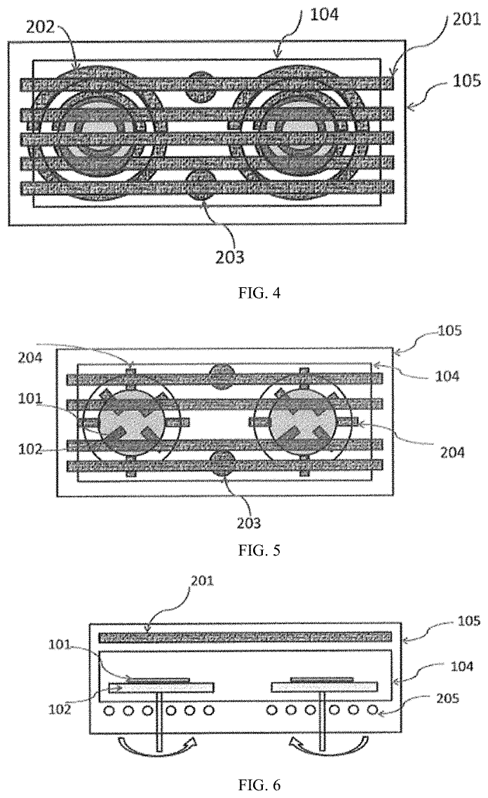

In an example, a top line heat source and a bottom arc heat source are combined with a point (small plane) heat source, a shape and an arrangement of the heating body (the heat source) are shown in FIG. 3 and FIG. 4, the heating body 201 is a line heater perpendicular or parallel to connecting line of circle centers of the disc bases 102, that is, a long-strip-shaped heat source, 203 is a point heat source or a smaller line or plane heat source. The heating body 202 is a ring heater using circle center of the disc base 102 as a center, or a section of arc heater (heat source) located on the ring or a complete disc heater, for example, a spiral heater.

In the modification of the above example, a top line heat source is combined with a bottom radial line heat source, and a shape and an arrangement of the heating body (the heat source) are shown in FIG. 5. A heating body 204 is a radial line heater of the disc base 102, that is, a short-strip-shaped heat source.

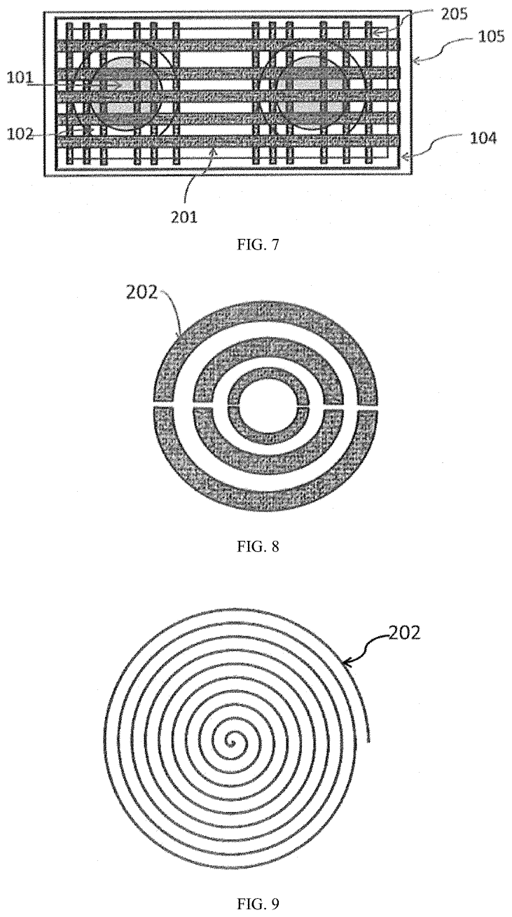

In another example, a top line heat source and a bottom line heat source are perpendicular to each other, and a shape and an arrangement of the heating body (the heat source) are shown in FIG. 6 and FIG. 7. A heating body 205 is a line heater perpendicular to connecting line of circle centers of the disc bases (that is, a long-strip-shaped heat source).

According to an embodiment of the present invention, a heating body 202 may be any one or a combination of ring heaters as shown in FIG. 8 to FIG. 10. As shown in FIG. 8, a heating body may be an arc on a ring using circle center of the disc base 102 as a center.

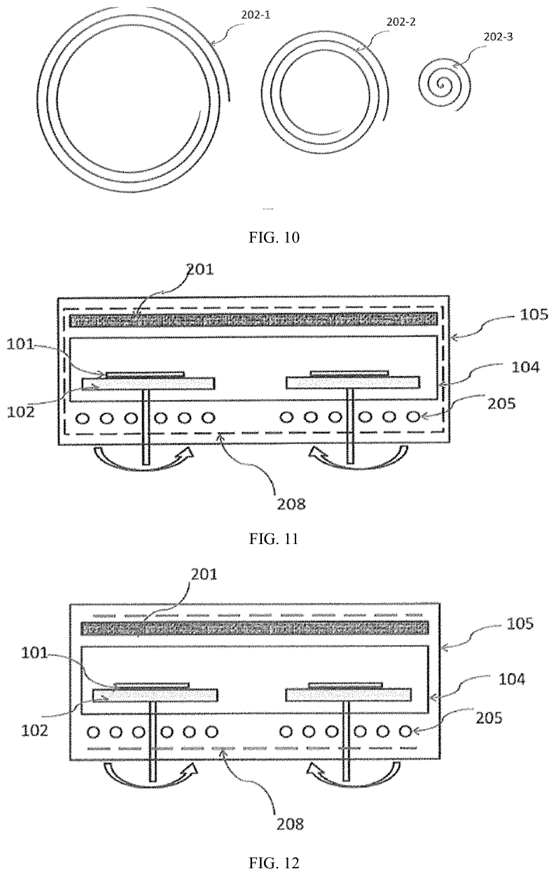

As another example, as shown in FIG. 9, a heating body is in a shape of a spiral, and the spiral forms a ring, or a complete circle, the circle center of the ring or circle is the same as the circle center of the disc base 102. Further, as shown in FIG. 10, 202-1 is an outermost ring spiral resistance heater, 202-2 is a smaller ring spiral heater on inner side, and 202-3 is a smaller disc-shaped spiral heater in the center. In this way, a complete disc-shaped heater is divided into two ring-shaped heaters 202-1, 202-2, and a small disc-shaped heater 202-3 in the center, and each heater is independently controlled to achieve zone control of temperature of the disc base.

A spiral resistance heater has a great effect on higher temperature process. For high temperature process, it is a common practice to use graphite or graphite coating materials to make resistance heaters. Because graphite heaters are usually obtained by directly cutting a large piece of graphite material, and graphite is also lacking in elasticity, it is difficult to form a structure similar to a spring to absorb stress caused by thermal expansion during temperature raising process. The graphite can be machined into a spiral structure by simple machine cutting. The spiral structure can be simply analogized to a circle with a gradually expanding radius from a center. Compared with a real circle, the spiral structure can obtain 10 times or more of circumference of the circle. At the same time, when thermal expansion occurs, the stress can be uniformly released to each length of the spiral, so that the stress per unit length is minimized. In this way, life of heater is improved, stability of equipment is improved, and cost is reduced.

In addition, heating bodies can be point heat sources or smaller line or plane heat sources, and are distributed on a plurality of rings using circle center of the disc base 102 as a center, or the heating bodies can be point heat sources, and are distributed in a honeycomb pattern, and center of the point heat sources is the circle center of the disc base 102. This is not limited in the present invention.

Further, the above heating bodies can be connected in series or in parallel as required. After several heaters are connected in series or parallel, the several heaters are separately and independently controlled from other heaters connected in series or parallel, so as to implement zone control of temperature on the disc base 102 to achieve better uniformity of film formation.

Specifically, a single line heater parallel to connecting line of circle centers of the disc bases 102 can heat two bases at the same time and use the same power source. For example, a power module such as a thyristor or an IGBT is used to control, so that production cost of heater can be reduced. Line heater perpendicular to the connecting line of the circle centers of the disc bases 102, and other centrosymmetric heating bodies (heat sources), can be connected in series or in parallel with heating bodies of corresponding parts of the other disc base 102, and the same heating power supply is used to control, so that the production cost of the heating power source can be effectively reduced, and good uniformity of film formation can be stilled obtained.

An arrangement of the above heaters, several combinations are described as follows:

A line heater (that is, a long-strip-shaped heat source) is used. A line heater parallel to connecting line of circle centers of the disc bases 102 is arranged above the disc, and a line heater perpendicular to the connecting line of the circle centers of the disc bases 102 is arranged below the disc. Alternatively, on the contrary, a line heater perpendicular to connecting line of circle centers of the disc bases 102 is arranged above the disk, and a line heater parallel to the connecting line of the circle centers of the disc bases 102 is arranged below the disk. A point heater (a point heat source) or a ring heater is arranged at another location as a line heater (that is, a long-strip-shaped heat source) for supplement and adjustment. Alternatively, a line heater parallel to connecting line of circle centers of the disc bases 102 is arranged above the disc, and a point heater (a point heat source) or a ring heat source is arranged below the disc. Alternatively, interchange is performed.

Heat of heaters may directly pass through the inner box 104, such as an inner box made of quartz, to heat the disc base 102 and the substrate 101; or indirectly heat the inner box 104, such as an inner box made of coated graphite, and then indirectly heat the disc base 102 and the substrate 101 by radiation of the inner box 104. When reactant gas flows over surface of heated substrate, the reactant gas can form a film on the surface of the substrate, that is, chemical vapor deposition occurs.

It can be understood that temperature measurement devices such as infrared sensors or thermocouples can be used to detect temperature of various parts of the substrate, and control power of different heating bodies/heat sources according to process requirements, that is, zone control, so that the temperature of the substrate is uniform.

According to an embodiment of the present invention, as shown in FIG. 11 and FIG. 12, a high reflectivity or high emissivity material 208 may be provided between the heater and the reaction chamber 105, for example, oxide, nitride or carbide materials, such as gold-plated plates, etc., obtained by sintering or other molding processes, and these materials can block heat radiation, reduce energy consumption, and at the same time reduce temperature of surface of the metal reaction chamber 105 to play a role of protection. FIG. 11 is a completely enclosed reflective box 208. In FIG. 12, only two plates 208 are provided on surfaces having two large surface areas on the top and at the bottom. The material with high reflectivity (emissivity) can be a single piece of material. For example, one thin sheet shields the front of the reaction chamber 105, or a plurality of thin sheets shields different planes or areas to form a combination. Alternatively, the material with high reflectivity (emissivity) may be a complete closed container similar to the inner box 104 or the reaction chamber 105, or high reflective (emissivity) materials may be attached to inner surface of the reaction chamber 105 (a metal container) or outer surface of the inner box 104 by spraying, depositing, or attaching.

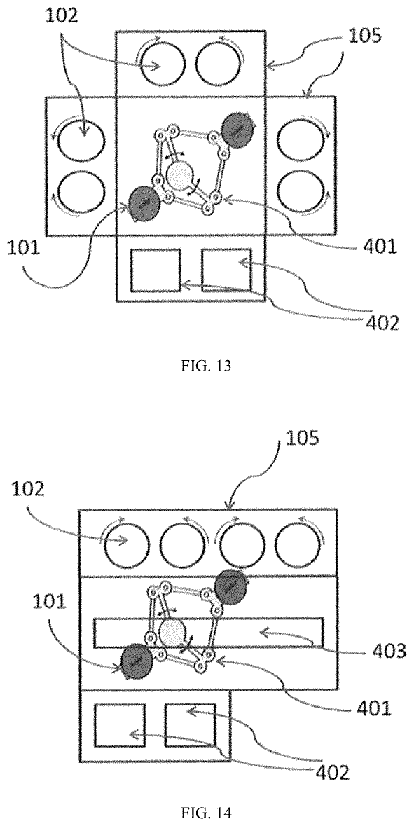

According to an embodiment of the present invention, FIG. 13 and FIG. 14 are configuration of a pipeline of the present invention. In FIG. 12 and FIG. 13, 401 is a mechanical transfer arm for transferring substrates, 402 is a cassette for storing substrates, and 403 is a guide rail for linear movement of the mechanical transfer arm.

As an example, a polygonal transfer chamber can be set, and the polygon is trigon, quadrilateral, pentagon, hexagon, heptagon, or octagon at most. Except for one or two sides of the polygon as a transfer station for the system to transfer the substrate 101 outwards, each of the remaining sides of the polygon is provided with the reaction chamber 105 of the plurality of disc bases 102 described above. The mechanical transfer arm 401 is located at center point of the polygon, the mechanical transfer arm 401 can rotate around the center of the polygon for 360 degrees, and the mechanical transfer arm 401 can move forward and backward in a radial direction at the same time. The mechanical transfer arm 401 extends radially into the disc base 102 on each side of the polygon to transfer the substrate 101, and then rotates to a position (side) on the polygon where the disc base 102 is not arranged in the reaction chamber 105 to transfer the substrate 101 out of the system. On the contrary, the mechanical transfer arm 401 transfers the substrate 101 from outside to the disc base 102 in the reaction chamber 105 through the polygonal transfer chamber.

As shown in FIG. 13, the transfer chamber is quadrilateral, the center of which is a mechanical transfer arm 401, a reaction chamber 105 with two disc bases 102 is provided on each of three sides, and the fourth side is the cassette 402 for transferring the substrate 101. The mechanical transfer arm 401 transfers the substrate 101 stored in the cassette 402 into the reaction chamber 105 or transfers the substrate 101 from the reaction chamber 105 to the cassette 402.

As shown in FIG. 14, as described above, circle centers of the plurality of disc bases 102 are located on a same straight line. A mechanical transfer arm 401 is arranged on one side of these disc bases 102. A base of the mechanical transfer arm 401 can move along a direction parallel to connecting line of the circle centers of the disc bases 102. Before moving along a direction parallel to the connecting line of the circle centers of these disc bases 102 to each disc base 102, an arm on the base of the mechanical transfer arm can transfer the substrate 101 to the reaction chamber 105 and place the substrate 101 on the disc base 102 or transfer the substrate 101 out of the reaction chamber 105. The cassette 402 may be located on the other side of the mechanical transfer arm 401 relative to the disc base 102, or may be located at both ends of the mechanical transfer arm 401.

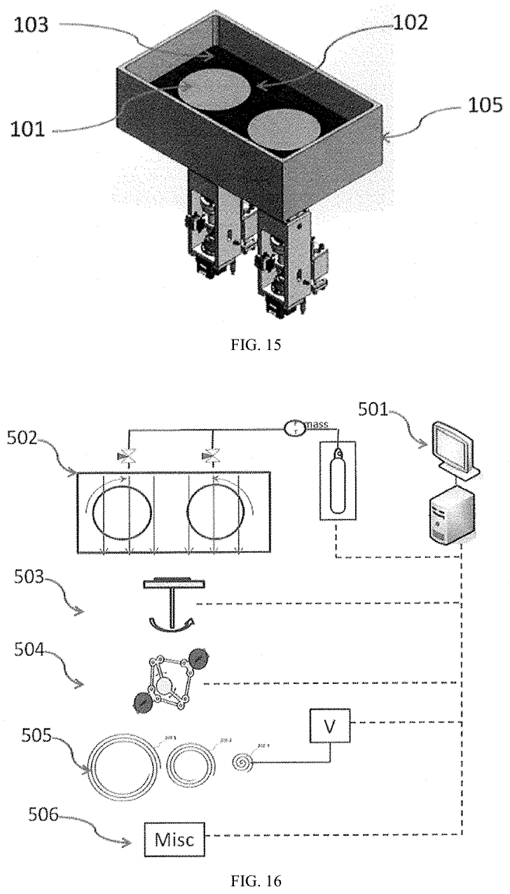

Referring to FIG. 15 and FIG. 16, a chemical vapor deposition process system is briefly described. The system includes chemical vapor deposition equipment according to an embodiment of the present invention. FIG. 15 is a three-dimensional model established when designing an embodiment of the present invention. FIG. 15 is a simplification version of the three-dimensional model, and only the reaction chamber 105, the substrate 101, the disc base 102, the base extension part 103 and a rotating mechanism of the disc base are shown in FIG. 15.

FIG. 16 is a schematic connection diagram of a chemical vapor deposition process system. 501 is a control unit of equipment, including an industrial computer, a single-chip microcomputer, a programmable PLC, an Ethernet controller, an image man-machine interface, etc. to control the reaction chamber and other units; 502 is a gas module, including a gas cabinet, a mass flow meter, various gas channel valves, gas distributors, etc.; 503 is a mechanical control unit that rotates and lifts the base; 504 is a substrate transport system, such as a mechanical arm, a cassette control system, etc.; 505 is a heater power supply silicon controlled thyristor or IGBT or another power module, a temperature measurement sensor, a temperature control algorithm unit, etc. 506 is additional auxiliary unit, such as a safety interlock, a control mechanism for a pump (under a reduced pressure), a heat exhaust fan, etc.

In conclusion, in the present invention, two or more disc bases can be arranged at low cost, and these disc bases can share gas flow controllers or fewer heaters by using pipelines. In this way, film-formation can be performed on more disc bases, and costs of reaction chamber and gas control loop, heater, heater power supply, and substrate conveying system supporting the reaction chamber are greatly reduced, so that manufacturing cost of the entire set of equipment is reduced. At the same time, consumption of energy for heating can also be reduced, so that the amount of consumables for film formation can also be reduced. In addition, the same film uniformity as the single-piece disc base is achieved while the above low-cost solution is implemented.

A lot of specific details are explained in the specification provided herein. However, it can be understood that the embodiments of the present invention can be practiced without these specific details. In some instances, well-known methods, structures and technologies are not shown in detail, so as not to obscure the understanding of this specification.

Similarly, it should be understood that, to streamline this disclosure and help understand one or more of the various aspects of the invention, in the foregoing descriptions of embodiments of the present invention made for illustration purposes, various features of the present invention are sometimes grouped into a single embodiment, a drawing, or their respective descriptions. However, a way of disclosing should not be interpreted as reflecting the following intention: the claimed present invention requires more features than those clearly disclosed in each claim. More accurately, as reflected in the claims below, the aspects of invention are less than all features of a single embodiment that is previously disclosed. Therefore, the claims that follow a specific implementation manner definitely incorporate the specific implementation manner. Each claim serves as a separate embodiment of the present invention.

Persons skilled in the art may understand that modules in devices in the embodiments may be adaptively changed and be disposed in one or more devices that are different from those of these embodiments. Modules or units or components in the embodiments may be combined into a module or a unit or a component, and additionally, may be divided into a plurality of submodules or subunits or subcomponents. Except a fact that at least some of these features and/or processes or units are mutually exclusive, all disclosed features and all processes or units of any method or device that are disclosed in such a way in this specification (including the appended claims, the abstract, and the accompanying drawings) may be combined in any combination mode. Unless otherwise explicitly stated, each feature disclosed in this specification (including the appended claims, the abstract, and the accompanying drawings) may be replaced by an alternative feature that serves same, equivalent, or similar purposes.

In addition, persons skilled in the art can understand that, although some embodiments described herein include some features included in another embodiment instead of including another feature, a combination of features of different embodiments means falling within the scope of the present invention and forming different embodiments. For example, in the claims, any one of the claimed embodiments may be used in any combination mode.

It should be noted that the foregoing embodiments are intended for describing the present invention, instead of limiting the present invention, and persons skilled in the art may design an alternative embodiment without departing from the scope of the appended claims. In the claims, any reference symbol between the brackets shall not constitute any limitation on the claims. The word “comprise” does not exclude existence of an element or a step that is not listed in the claims. The word “a/an” or “one” preceding an element does not exclude existence of multiple such elements. The present invention may be implemented by hardware including several different elements and a computer that is appropriately programmed. In unit claims that list several apparatuses, some of the apparatuses may be specifically implemented by a same hardware item. Use of words first, second, third, and the like does not indicate any sequence. These words may be interpreted as names.

Although various aspects and embodiments have been disclosed herein, other aspects and embodiments are apparent to the persons skilled in the art. The various aspects and embodiments disclosed herein are for illustrative purposes and are not intended to limit, and the true scope should be indicated by the appended claims and the full scope of equivalents authorized by such claims. It should further be understood that the terms used herein are only for the purpose of describing specific embodiments and are not intended to limit.

1. A chemical vapor deposition equipment, comprising a reaction chamber, the reaction chamber comprises a plurality of bases for bearing substrates, the plurality of bases are disc-shaped, and process gas enters the reaction chamber through a pipeline, wherein
each base of the plurality of bases is arranged in parallel to each other, and circle centers of the bases are on a same straight line;
upper surfaces of the bases bearing the substrates are parallel to each other or on a same plane;
rotation axes of the bases are on a same plane, and the bases rotate independently relative to each other; and
the process gas flows along the upper surfaces of the bases and in a direction perpendicular to a connecting line of the circle centers of the bases.

2. The chemical vapor deposition equipment according to claim 1, wherein an inner box is further comprised between the reaction chamber and the bases, and a shape of the inner box comprises a cuboid; and
the reactant gas flows along the upper surfaces of the bases and flows in a direction relatively parallel to short sides of a rectangle obtained by cutting by using the upper surfaces and a cross section of the inner box.

3. The chemical vapor deposition equipment according to claim 1, wherein the adjacent bases rotate in directions opposite to each other.

4. The chemical vapor deposition equipment according to claim 1, wherein the chemical vapor deposition equipment further comprises a mass flow meter, the mass flow meter is used for the plurality of bases, and the mass flow meter distributes the process gas to the bases; and
a regulating valve is disposed on the pipeline through which the process gas flows from the mass flow meter to the bases.

5. The chemical vapor deposition equipment according to claim 1, wherein the chemical vapor deposition equipment further comprises a transfer chamber and a mechanical transfer arm, the transfer chamber is polygonal, at least one side of the transfer chamber is provided with a transfer station of the substrate, and the reaction chamber is provided on each of the remaining sides; and
the mechanical transfer arm is located in the transfer chamber, and transfers the substrate to the plurality of bases of the reaction chamber.

6. The chemical vapor deposition equipment according to claim 5, wherein the mechanical transfer arm is further configured to move along a direction parallel to the connecting line of the circle centers of the bases in the reaction chamber.

7. The chemical vapor deposition equipment according to claim 1, wherein a base extension part is filled between the bases, a material of the base extension part is the same as that of the bases, and an upper surface of the base extension part and the upper surfaces of the bases are on a same plane.

8. The chemical vapor deposition equipment according to claim 7, wherein the upper surface of the base extension part comprises one or more of a shield, a protrusion, a depression, a guide fin, or a positioning point.

9. The chemical vapor deposition equipment according to claim 7, wherein an elevation difference is between the upper surface of the base extension part and the upper surfaces of the bases, and the elevation difference can be adjusted manually or automatically by using a mechanical structure.

10. The chemical vapor deposition equipment according to claim 2, wherein the inner box is made of a non-metallic high-temperature-resistant and corrosion-resistant material.

11. The chemical vapor deposition equipment according to claim 2, wherein a heating body is provided between the reaction chamber and the inner box, the heating body comprises an infrared lamp source, a resistance heater, and the resistance heater comprises a metal or graphite resistance heater.

12. The chemical vapor deposition equipment according to claim 1, wherein a driving mode of the metal resistance heater or the graphite resistance heater further comprises exciting metal or graphite by using an induction coil radio frequency, to cause the metal resistance heater or the graphite resistance heater to generate heat.

13. The chemical vapor deposition equipment according to claim 11, wherein the resistance heater is spiral shaped.

14. The chemical vapor deposition equipment according to claim 11, wherein the resistance heater further comprises at least one of following heaters:
a ring heater centered on the circle centers of the bases;
an arc heater centered on the circle centers of the bases;
point heaters, wherein the point heaters are distributed on a plurality of rings centered on the circle centers of the bases, or distributed in a honeycomb pattern centered on the circle centers of the bases; and
line heaters, wherein the line heaters are distributed in a direction perpendicular or parallel to the connecting line of the circle centers of the bases, or the line heaters are distributed along a radial direction of the bases.

15. The chemical vapor deposition equipment according to claim 11, wherein a heat-insulation material is provided between the heating body and the reaction chamber, and the heat-insulation material is a high emissivity material or a high reflectivity material.
